(19) United States
(12) Patent Application Publication
(10) Pub. No.: US 2025/0285961 A1
(43) Pub. Date: Sep. 11, 2025

(54) SEMICONDUCTOR DEVICE AND METHOD OF MANUFACTURING SEMICONDUCTOR DEVICE

(71) Applicant: SK hynix Inc., Gyeonggi-do (KR)

(72) Inventor: Young Ock HONG, Gyeonggi-do (KR)

(21) Appl. No.: 18/676,527

(22) Filed: May 29, 2024

(30) Foreign Application Priority Data
Mar. 6, 2024 (KR) 10-2024-0032127

(51) Int. Cl. H01L 23/522; H01L 23/00; H01L 23/528; H01L 25/065; H10B 80/00

(52) U.S. Cl. CPC H01L 23/5226; H01L 23/5283; H01L 24/08; H01L 24/16; H01L 25/0657; H01L 2224/08146; H01L 2224/08225; H01L 2224/16146; H01L 2224/16227; H01L 2225/06517; H01L 2225/06541; H01L 2924/01029; H01L 2924/01074; H01L 2924/1431; H01L 2924/1434; H10B 80/00

(57) ABSTRACT

A semiconductor device may include a first semiconductor structure including a peripheral circuit and an interconnection structure electrically connected to the peripheral circuit, a second semiconductor structure, a bonding layer positioned between the first and second semiconductor structures, a bonding pad electrically connected to the interconnection structure, the bonding pad extending into the bonding layer, and a contact plug extending into the bonding layer through the second semiconductor structure, wherein the contact plug is electrically connected to the bonding pad.

### CROSS-REFERENCE TO RELATED APPLICATION

This application claims priority under 35 U.S.C. § 119 to Korean Patent Application No. 10-2024-0032127 filed on Mar. 6, 2024, which is incorporated herein by reference in its entirety.

### BACKGROUND

### 1. Technical Field

Embodiments of the present disclosure relate to an electronic device, and more particularly, to a semiconductor device and a method of manufacturing the semiconductor device.

### 2. Related Art

An integration degree of a semiconductor device is mainly determined by a region occupied by a unit memory cell. Recently, as improvements in the integration degree of a semiconductor device in which a memory cell is formed as a single layer on a substrate reach a limit, a three-dimensional semiconductor device in which memory cells are stacked on a substrate is being proposed. In addition, various structures and manufacturing methods are being developed in order to improve operation reliability of the semiconductor device.

### SUMMARY

According to an embodiment of the present disclosure, a semiconductor device may include a first semiconductor structure including a peripheral circuit and an interconnection structure electrically connected to the peripheral circuit, a second semiconductor structure, a bonding layer positioned between the first and second semiconductor structures, a bonding pad electrically connected to the interconnection structure, the bonding pad extending into the bonding layer, and a contact plug extending into the bonding layer through the second semiconductor structure, wherein the contact plug is electrically connected to the bonding pad.

According to an embodiment of the present disclosure, a semiconductor device may include a first bonding layer, a first bonding pad passing through the first bonding layer, a second bonding layer forming a bonding interface with the first bonding layer, a first gate structure on the second bonding layer, and a first contact plug extending through the first gate structure and the second bonding layer and electrically connected to the first bonding pad, and the first contact plug may include a metal layer, and a barrier layer surrounding a sidewall of the metal layer and extending between the metal layer and the first bonding pad.

According to an embodiment of the present disclosure, a method of manufacturing a semiconductor device may include forming a first wafer including a first bonding layer and a first bonding pad, forming a second wafer including a second bonding layer and a first sacrificial plug, bonding the first bonding layer and the second bonding layer so that the first bonding pad and the first sacrificial plug are connected, forming a first opening exposing the first bonding pad by removing the first sacrificial plug, and forming a first contact plug electrically connected to the first bonding pad, in the first opening.

### BRIEF DESCRIPTION OF THE DRAWINGS

FIGS. 1A and 1B are diagrams illustrating a structure of a semiconductor device according to an embodiment of the present disclosure.

FIGS. 2A and 2B are cross-sectional views illustrating a structure of a semiconductor device according to an embodiment of the present disclosure.

FIG. 3 is a diagram illustrating a structure of a semiconductor device according to an embodiment of the present disclosure.

FIGS. 4A to 4C are diagrams illustrating a structure of a semiconductor device according to an embodiment of the present disclosure.

FIGS. 5A to 5D are diagrams illustrating a method of manufacturing a semiconductor device according to an embodiment of the present disclosure.

FIGS. 6A to 6C are diagrams illustrating a method of manufacturing a semiconductor device according to an embodiment of the present disclosure.

FIGS. 7A to 7C are diagrams illustrating a method of manufacturing a semiconductor device according to an embodiment of the present disclosure.

FIGS. 8A to 8G are diagrams illustrating a method of manufacturing a semiconductor device according to an embodiment of the present disclosure.

FIG. 9 is a configuration diagram of a semiconductor device according to an embodiment of the present invention disclosure.

FIG. 10 is a configuration diagram of a semiconductor device according to an embodiment of the present invention disclosure.

### DETAILED DESCRIPTION

Embodiments of the present disclosure provide a semiconductor device and a method of manufacturing the semiconductor device having a stable structure and improved performance characteristics.

The integration degree of the semiconductor device is improved by stacking memory cells in a three-dimensional structure. In addition, the semiconductor device with the three-dimensional structure has a stable structure, and exhibits improved reliability and performance.

Hereinafter, embodiments according to the technical concepts of the present disclosure are described with reference to the accompanying drawings.

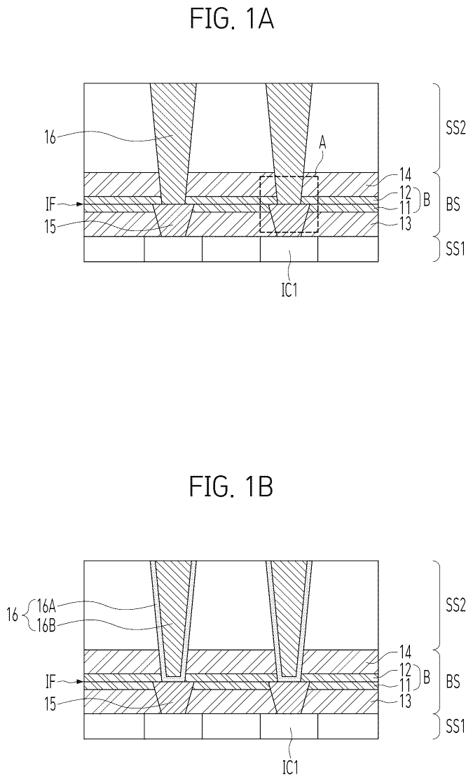

FIGS. 1A and 1B are diagrams illustrating a structure of a semiconductor device according to an embodiment of the present disclosure.

Referring to FIG. 1A, the semiconductor device may include a first semiconductor structure SS1, a second semiconductor structure SS2, and a bonding structure BS disposed between the first and second semiconductor structures SS1, and SS2. The semiconductor device may further comprise at least one contact plug 16, e.g., two or more contact plugs 16. For example, the first semiconductor structure SS1 and the second semiconductor structure SS2 may include a peripheral circuit and/or a memory cell array. In an embodiment, the first semiconductor structure SS1 may include the peripheral circuit. The first semiconductor structure SS1 may further include a first interconnection structure IC1 electrically connected to the peripheral circuit, an interlayer insulating layer, and the like. In an embodiment, the second semiconductor structure SS2 may include the memory cell array. The second semiconductor structure SS2 may include a source structure, a gate structure, a channel structure, a second interconnection structure, an interlayer insulating layer, and the like. The memory cell array may include memory cells stacked along a channel structure. In an embodiment, the first semiconductor structure SS1 may include the memory cell array, and the second semiconductor structure SS2 may include the peripheral circuit.

The bonding structure BS electrically connects the first semiconductor structure SS1 and the second semiconductor structure SS2 by bonding the first semiconductor structure SS1 and the second semiconductor structure SS2. The bonding structure BS may include a bonding layer B and first and second bonding insulating layers 13 and 14. The bonding layer B may be disposed between the first and second bonding insulating layers 13 and 14. The bonding layer B may include a first bonding layer 11 and a second bonding layer 12. At least one bonding pad 15, e.g., two or more bonding pads 15 may be disposed within the bonding structure BS.

The first and second bonding layers 11 and 12 may form a bonding interface IF. The first bonding layer 11 may be positioned over the first semiconductor structure SS1. The first bonding layer 11 may be positioned on the first bonding insulating layer 13. The second bonding layer 12 may be positioned between the first bonding layer 11 and the second bonding insulating layer 14. The first bonding insulating layer 13 may be positioned between the first semiconductor structure SS1 and the first bonding layer 11. The second bonding insulating layer 14 may be positioned between the second semiconductor structure SS2 and the second bonding layer 12. The bonding interface IF may be positioned at a portion where the first and second bonding layers 11 and 12 are in contact with each other. The first and second bonding layers 11 and 12 may be chemically bonded at the bonding interface IF.

In an embodiment, the first and second bonding layers 11 and 12 may include tetraethylorthosilicate (TEOS), silicon carbon nitride (SiCN), or the like. When bonding the first and second bonding layers 11 and 12 formed of a SiCN layer, Si—O—Si bonding may be generated on a surface of the first and second bonding layers 11 and 12, and the bonding interface IF may be changed to an oxide such as tetraethylorthosilicate (TEOS) by removing carbon and nitrogen from SiCN.

The first bonding insulating layer 13 may be positioned between the first semiconductor structure SS1 and the first bonding layer 11 for protecting the first bonding layer 11 in a manufacturing process. The first bonding insulating layer 13 may be a single layer. The first bonding insulating layer 13 may be multiple layers. The second bonding insulating layer 14 may be positioned between the second semiconductor structure SS2 and the second bonding layer 12 for protecting the second bonding layer 12 in the manufacturing process. The second bonding insulating layer 14 may be a single layer. The second bonding insulating layer 14 may be multiple layers. The first and second bonding insulating layers 13 and 14 may include the same or different insulating material such as, for example, an oxide, a nitride, or TEOS.

The bonding pad 15 may extend into the bonding layer B and may pass through the first bonding layer 11. In an embodiment, the bonding pad 15 may extend through the first bonding layer 11 and the first bonding insulating layer 13 to electrically connect to the first interconnection structure IC1. The bonding pad 15 may be electrically connected to the peripheral circuit of the first semiconductor structure SS1 through the first interconnection structure IC1.

The contact plug 16 may extend into the bonding layer B through the second semiconductor structure SS2, and may pass through the second bonding layer 12. In an embodiment, the contact plug 16 may extend through the gate structure, the source structure, the interlayer insulating layer, and the like of the second semiconductor structure SS2, and may pass through the second bonding insulating layer 14. The contact plug 16 may be electrically connected to the bonding pad 15 at the bonding interface IF.

Referring to FIG. 1B, the contact plug 16 may include a barrier layer 16A and a metal layer 16B in the barrier layer 16A. The barrier layer 16A may surround a sidewall of the metal layer 16B and may extend between the metal layer 16B and the bonding pad 15. The barrier layer 16A may be in contact with the bonding pad 15. The barrier layer 16A may have a substantially uniform thickness along its entire extent.

According to the structure described above, the bonding structure BS may include the bonding pad 15 corresponding to the first semiconductor structure SS1 and may not include a bonding pad corresponding to the second semiconductor structure SS2. Instead, the contact plug 16 passing through the second semiconductor structure SS2 may be directly connected to the bonding pad 15. The contact plug 16 may pass through the second semiconductor structure SS2, the second bonding insulating layer 14, and the second bonding layer 12, and may be directly connected to the bonding pad 15.

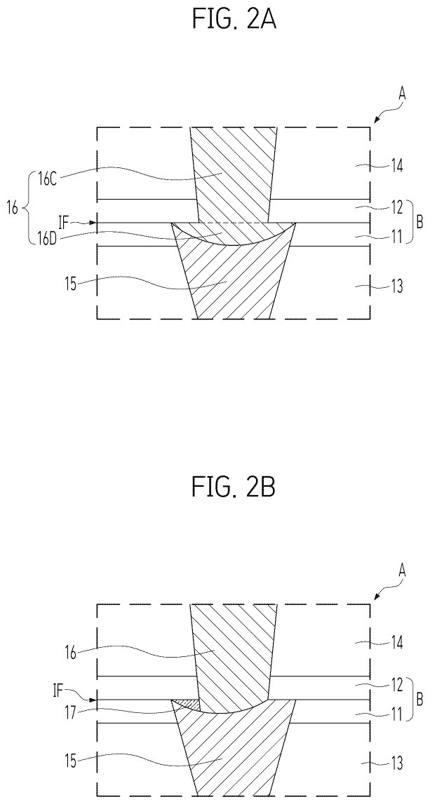

FIGS. 2A and 2B are cross-sectional views illustrating a structure of a semiconductor device according to an embodiment of the present disclosure. FIGS. 2A and 2B are enlarged views of a region A of FIG. 1A. Hereinafter, a description that overlaps the content described above may be omitted.

Referring to FIG. 2A, the semiconductor device may include a first bonding layer 11, a second bonding layer 12, a first bonding insulating layer 13, a second bonding insulating layer 14, a bonding pad 15, and a contact plug 16. The contact plug 16 may pass through the second bonding insulating layer 14 and the second bonding layer 12 and may extend into the first bonding layer 11.

A lower surface of the contact plug 16 may be in contact with the bonding pad 15. A contact surface of the contact plug 16 and the bonding pad 15 may be flat or may include a curved surface. In an embodiment, an upper surface of the bonding pad 15 may be positioned lower than an upper surface of the first bonding layer 11 and may include a curved surface. This structure may be due to dishing induced in a planarization process. A step may exist between the upper surface of the bonding pad 15 and the upper surface of the first bonding layer 11 due to dishing, and the step may be filled with the contact plug 16.

The contact plug 16 may include a through portion 16C and an expansion portion 16D. The through portion 16C may pass through the second bonding layer 12 and the second bonding insulating layer 14, and may extend into the second semiconductor structure SS2. The through portion 16C may have a cross-section of a taper shape or a bowing shape. The expansion portion 16D may fill the step between the bonding pad 15 and the first bonding layer 11. The expansion portion 16D may extend into the first bonding layer 11 and may have a width greater than that of the through portion 16C. The expansion portion 16D may have a flat upper surface at the bonding interface IF, and a lower surface that is in contact with the bonding pad 15 may include a curved surface.

Referring to FIG. 2B, the semiconductor device may include a first bonding layer 11, a second bonding layer 12, a first bonding insulating layer 13, a second bonding insulating layer 14, a bonding pad 15, and a contact plug 16. The contact plug 16 may pass through the second bonding insulating layer 14 and the second bonding layer 12, and may extend into the first bonding layer 11.

A foreign substance 17 may exist between the bonding pad 15 and the second bonding layer 12. The foreign substance 17 may be a by-product caused in the manufacturing process. In an embodiment, the foreign substance 17 may be an etching by-product or a bonding by-product, or may be a polymer-based material. The foreign substance 17 may not exist between the bonding pad 15 and the contact plug 16.

According to the structure described above, the contact plug 16 may be expanded into the first bonding layer 11. A lower surface of the contact plug 16 may include a curved surface and may protrude into the bonding pad 15. Therefore, a contact area of the bonding pad 15 and the contact plug 16 may be increased, and the foreign substance 17 may be removed between the bonding pad 15 and the contact plug 16 to improve a bonding defect.

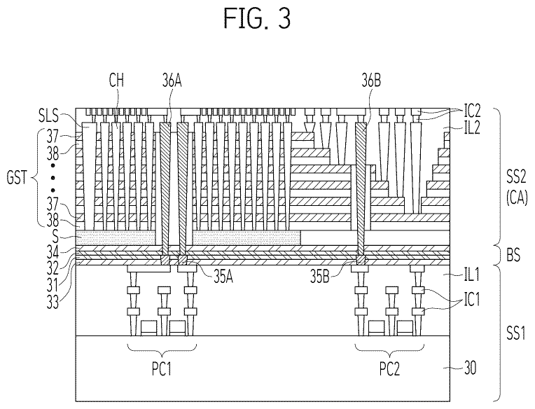

FIG. 3 is a diagram illustrating a structure of a semiconductor device according to an embodiment of the present disclosure. Hereinafter, a description that overlaps the content described above may be omitted.

Referring to FIG. 3, the semiconductor device may include a first semiconductor structure SS1, a second semiconductor structure SS2, a bonding structure BS, and contact plugs 36A and 36B. The bonding structure BS may be positioned between the first semiconductor structure SS1 and the second semiconductor structure SS2.

The first semiconductor structure SS1 may include a substrate 30, peripheral circuits PC1 and PC2, a first interlayer insulating layer IL1, and a first interconnection structure IC1. The first peripheral circuit PC1 may be a page buffer, and the second peripheral circuit PC2 may be a row decoder. The first interconnection structure IC1 may be positioned in the first interlayer insulating layer IL1. The first interconnection structure IC1 may be electrically connected to the peripheral circuits PC1 and PC2 and may include a via and/or a line.

The second semiconductor structure SS2 may include a source structure S, a gate structure GST, a channel structure CH, a slit structure SLS, a second interlayer insulating layer IL2, and a second interconnection structure IC2. A gate structure GST may be positioned on the source structure S, and the gate structure GST may include gate lines 37 and insulating layers 38 that are alternately stacked. In an embodiment, the gate lines 37 may be a source select line, a word line, and or a drain select line. Each of the channel structures CH may extend through the gate structure GST and may be connected to the source structure S. The slit structure SLS may extend through the gate structure GST and may include an insulating material, a semiconductor material, or a conductive material.

The second interconnection structure IC2 may be positioned in the second interlayer insulating layer IL2. The second interconnection structure IC2 may be connected to the channel structure CH, the slit structure SLS, the gate lines 37, and the like, and may include a via and/or a line. In an embodiment, the second interconnection structure IC2 may include one or more bit lines connected to the channel structures CH.

The bonding structure BS may include a first bonding layer 31, a second bonding layer 32, a first bonding insulating layer 33, a second bonding insulating layer 34, and bonding pads 35A and 35B. The contact plugs 36A and 36B may pass through the second semiconductor structure SS2, and may be directly connected to the bonding pads 35A and 35B. The peripheral circuits PC1 and PC2 and the memory cell array CA may be electrically connected through the contact plugs 36A and 36B and the bonding pads 35A and 35B.

In an embodiment, the first contact plug 36A may be connected to the bit line through the second interconnection structure IC2, and may extend through the gate structure GST and the source structure S. The first contact plug 36A may pass through the second bonding insulating layer 34 and the second bonding layer 32 to electrically connect to the first bonding pad 35A. In this case, the bit line of the memory cell array CA and the page buffer of the first peripheral circuit PC1 may be connected through the first contact plug 36A and the first bonding pad 35A.

In an embodiment, the second contact plug 36B may be connected to the gate line 37 through the second interconnection structure IC2, and may extend through the gate structure GST. The second contact plug 36B may pass through the second bonding insulating layer 34 and the second bonding layer 32 to electrically connect to the second bonding pad 35B. In this case, the gate line 37 of the memory cell array CA and the row decoder of the second peripheral circuit PC2 may be connected through the second contact plug 36B and the second bonding pad 35B.

According to the structure described above, the contact plugs 36A and 36B passing through the second semiconductor structure SS2 may extend into the bonding structure BS, and may be directly connected to the bonding pads 35A and 35B. Therefore, the bonding structure BS may be simplified.

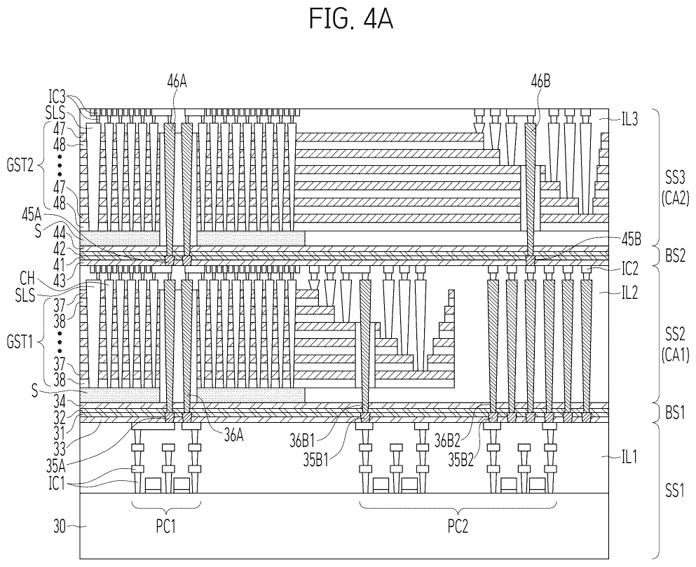

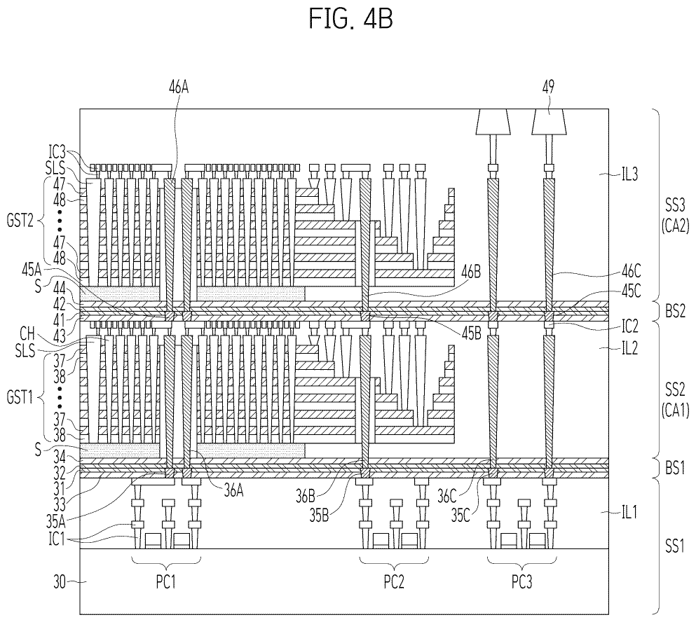

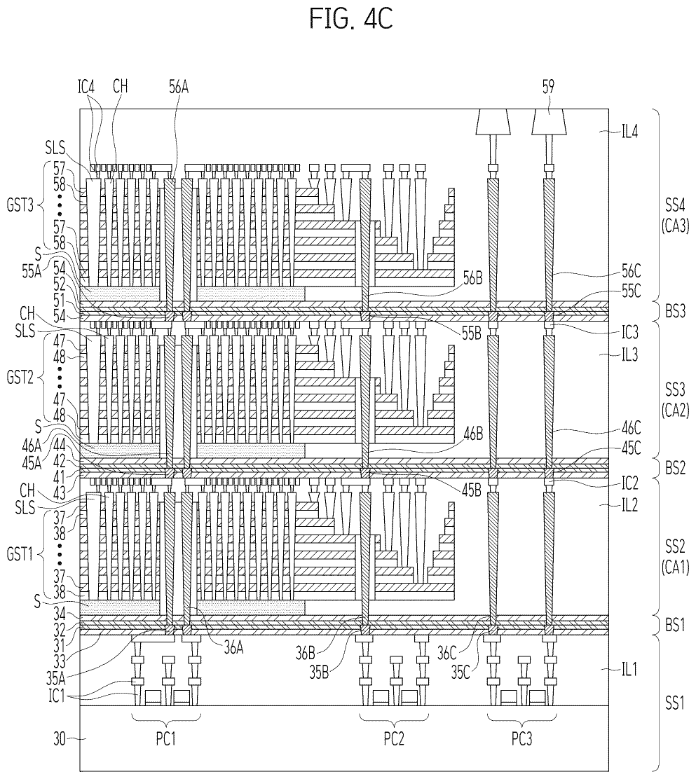

FIGS. 4A to 4C are diagrams illustrating a structure of a semiconductor device according to an embodiment of the present disclosure. Hereinafter, a description that overlaps the content described above may be omitted.

Referring to FIG. 4A, the semiconductor device may include first, second, and third semiconductor structures SS1, SS2, and SS3, first and second bonding structures BS1, and BS2, and contact plugs 36A, 36B1, 36B2, 46A, and 46B. The first bonding structure BS1 may be positioned between the first and second semiconductor structures SS1 and SS2. The second bonding structure BS2 may be positioned between the second and third semiconductor structures SS2 and SS3.

The first semiconductor structure SS1 may include a substrate 30, peripheral circuits PC1 and PC2, a first interlayer insulating layer IL1, and a first interconnection structure IC1. The first interlayer insulating layer IL1 may be formed on the substrate 30, and the first interconnection structure IC1 may be formed within the first interlayer insulating layer IL1. The second semiconductor structure SS2 may include a source structure S, a first gate structure GST1, a channel structure CH, a slit structure SLS, a second interlayer insulating layer IL2, and a second interconnection structure IC2. The first gate structure GST1 may include gate lines 37 and insulating layers 38 that are alternately stacked, and may include a first step structure.

The third semiconductor structure SS3 may include a source structure S, a second gate structure GST2, a channel structure CH, a slit structure SLS, a third interlayer insulating layer IL3, and a third interconnection structure IC3. A second gate structure GST2 may be positioned on the source structure S, and the second gate structure GST2 may include gate lines 47 and insulating layers 48 that are alternately stacked. In an embodiment, the gate line 47 may be a source select line, a word line, or a drain select line. The second gate structure GST2 may include a second step structure. The first step structure and the second step structure may be arranged in a staggered manner so as not to overlap.

The third interconnection structure IC3 may be positioned in the third interlayer insulating layer IL3. The third interconnection structure IC3 may be connected to the channel structure CH, the slit structure SLS, the gate lines 47, and the like, and may include a via and/or a line. In an embodiment, the third interconnection structure IC3 may include a bit line connected to the channel structure CH.

The first bonding structure BS1 may include first and second bonding layers 31 and 32, first and second bonding insulating layers 33 and 34, and bonding pads 35A, 35B1, and 35B2. The second bonding structure BS2 may include third and fourth bonding layers 41 and 42, third and fourth bonding insulating layers 43 and 44, and bonding pads 45A and 45B.

The contact plugs 46A and 46B may extend through the third semiconductor structure SS3 and may be directly connected to the bonding pads 45A and 45B. A first memory cell array CA1 and a second memory cell array CA2 may be electrically connected through the contact plugs 46A and 46B and the bonding pads 45A and 45B.

In an embodiment, the third contact plug 46A may be electrically connected to the bit line, and may extend through the second gate structure GST2 and the source structure S. The third contact plug 46A may pass through the fourth bonding insulating layer 44 and the fourth bonding layer 42 to electrically connect to the third bonding pad 45A. The third bonding pad 45A may be connected to the first contact plug 36A through the second interconnection structure IC2. In this case, the third contact plug 46A, the third bonding pad 45A, the first contact plug 36A, and the first bonding pad 35A may be electrically connected. Therefore, a bit line of the second memory cell array CA2 and a bit line of the first memory cell array CA1 may be commonly connected to the page buffer of the first peripheral circuit PC1.

In an embodiment, the fourth contact plug 46B may be electrically connected to a gate line of the second gate structure GST2, and may extend through the second step structure of the second gate structure GST2. The fourth contact plug 46B may pass through the fourth bonding insulating layer 44 and the fourth bonding layer 42 to electrically connect to the fourth bonding pad 45B. The fourth bonding pad 45B may be connected to the second contact plug 36B2 through the second interconnection structure IC2. In this case, the fourth contact plug 46B, the fourth bonding pad 45B, the second contact plug 36B2, and the second bonding pad 35B2 may be electrically connected. Therefore, the gate line 47 of the second memory cell array CA2 may be connected to the row decoder of the second peripheral circuit PC2.

Referring to FIG. 4B, the semiconductor device may include a first semiconductor structure SS1, a first bonding structure BS1, a second semiconductor structure SS2, a second bonding structure BS2, a third semiconductor structure SS3, and contact plugs 36A, 36B, 36C, 46A, 46B, and 46C.

A first gate structure GST1 of the second semiconductor structure SS2 may include a first step structure, and a second gate structure GST2 of the third semiconductor structure SS3 may include a second step structure. The first and second step structures may be positioned to overlap. The fourth contact plug 46B may extend through the second step structure, and the second contact plug 36B may extend through the first step structure. The fourth contact plug 46B, the fourth bonding pad 45B, the second contact plug 36B, and the second bonding pad 35B may be commonly connected to the second peripheral circuit PC2. Therefore, the first memory cell array CA1 and the second memory cell array CA2 may share the second peripheral circuit PC2, and the same operation voltage may be applied to the gate lines 37 and 47 positioned on the same layer.

The first bonding structure BS1 may further include a fifth bonding pad 35C, and the fifth contact plug 36C passing through the second semiconductor structure SS2 may be electrically connected to the fifth bonding pad 35C. The fifth contact plug 36C may extend into the first bonding structure BS1 through the second interlayer insulating layer IL2, and may be directly connected to the fifth bonding pad 35C.

The second bonding structure BS2 may further include a sixth bonding pad 45C, and the sixth contact plug 46C passing through the third semiconductor structure SS3 may be electrically connected to the sixth bonding pad 45C. The sixth contact plug 46C may extend into the second bonding structure BS2 through the third interlayer insulating layer IL3, and may be directly connected to the sixth bonding pad 45C. The sixth bonding pad 45C may be electrically connected to the fifth contact plug 36C through the second interconnection structure IC2.

The first semiconductor structure SS1 may further include a third peripheral circuit PC3. The third semiconductor structure SS3 may further include an uppermost metal line 49. The uppermost metal line 49 may be an external connection pad, a power transmission line, or a signal transmission line. Through the sixth contact plug 46C, the sixth bonding pad 45C, the fifth contact plug 36C, and the fifth bonding pad 35C, the uppermost metal line 49 and the third peripheral circuit PC3 may be electrically connected to each other. For example, the third peripheral circuit PC3 may be a logic circuit, an analog circuit, an input/output circuit, or the like.

Referring to FIG. 4C, the semiconductor device may include a first semiconductor structure SS1, a first bonding structure BS1, a second semiconductor structure SS2, a second bonding structure BS2, a third semiconductor structure SS3, a third bonding structure BS3, and a fourth semiconductor structure SS4 in the recited order. The semiconductor device may further include contact plugs 36A, 36B, 36C, 46A, 46B, 46C, 56A, 56B, and 56C.

The fourth semiconductor structure SS4 may include a source structure S, a third gate structure GST3, a channel structure CH, a slit structure SLS, a fourth interlayer insulating layer IL4, and a fourth interconnection structure IC4. The third gate structure GST3 may be positioned on the source structure S, and the third gate structure GST3 may include gate lines 57 and insulating layers 58 that are alternately stacked. In an embodiment, the gate line 57 may be a source select line, a word line, or a drain select line. The third gate structure GST3 may include a third step structure. The first step structure, the second step structure, and the third step structure may be arranged to overlap.

The fourth interconnection structure IC4 may be positioned in the fourth interlayer insulating layer IL4. The fourth interconnection structure IC4 may be connected to the channel structure CH, the slit structure SLS, the gate lines 57, and the like, and may include a via and/or a line. In an embodiment, the fourth interconnection structure IC4 may include a bit line connected to the channel structure CH.

The third bonding structure BS3 may include a fifth bonding layer 51, a sixth bonding layer 52, a fifth bonding insulating layer 53, a sixth bonding insulating layer 54, and bonding pads 55A, 55B, and 55C. The contact plugs 56A, 56B, and 56C may extend through the fourth semiconductor structure SS4, and may extend into the third bonding structure BS3 to be directly connected to the bonding pads 55A, 55B, and 55C.

In an embodiment, the seventh contact plug 56A may be electrically connected to the bit line, and may extend through the third gate structure GST3 and the source structure S. The seventh contact plug 56A may pass through the sixth bonding insulating layer 54 and the sixth bonding layer 52 to electrically connect to the seventh bonding pad 55A. Therefore, a first memory cell array CA1, a second memory cell array CA2, and a third memory cell array CA3 may share the page buffer of the first peripheral circuit PC1.

In an embodiment, the eighth contact plug 56B may be connected to the gate line 57 of the third memory cell array CA3, and may extend through the third step structure of the third gate structure GST3. The eighth contact plug 56B may pass through the sixth bonding insulating layer 54 and the sixth bonding layer 52 to electrically connect to the eighth bonding pad 55B. Therefore, the first memory cell array CA1, the second memory cell array CA2, and the third memory cell array CA3 may share the row decoder of the second peripheral circuit PC2.

In an embodiment, the ninth contact plug 56C may pass through the fourth interlayer insulating layer IL4 to electrically connect to the ninth bonding pad 55C. Therefore, through the ninth contact plug 56C, the ninth bonding pad 55C, the sixth contact plug 46C, the sixth bonding pad 45C, the fifth contact plug 36C, and the fifth bonding pad 35C, an uppermost metal line 59 and the third peripheral circuit PC3 may be electrically connected. For example, the third peripheral circuit PC3 may be a logic circuit, an analog circuit, an input/output circuit, or the like.

According to the structure described above, three or more semiconductor structures SS1, SS2, SS3, and SS4 may be multi-bonded. The contact plugs 36A, 36B, 36B1, and 36B2 passing through the second semiconductor structure SS2 may extend into the first bonding structure BS1, and may be directly connected to the bonding pads 35A, 35B, 35B1, and 35B2. The contact plugs 46A, 46B, and 46C passing through the third semiconductor structure SS3 may extend into the second bonding structure BS2, and may be directly connected to the bonding pads 45A, 45B, and 45C. The contact plugs 56A, 56B, and 56C passing through the fourth semiconductor structure SS4 may extend into the third bonding structure BS3, and may be directly connected to the bonding pads 55A, 55B, and 55C. Therefore, the bonding structures BS1, BS2, and BS3 may be simplified.

In addition, the peripheral circuits PC1 and PC2 and the memory cell arrays CA1 and CA2 may be electrically connected through the bonding pads 35A, 35B1, 35B2, 45A, 45B, 55A, and 55B and the contact plugs 36A, 36B1, 36B2, 46A, 46B, 56A, and 56B. Therefore, the first memory cell array CA1 and the second memory cell array CA2 may share the peripheral circuits PC1 and PC2.

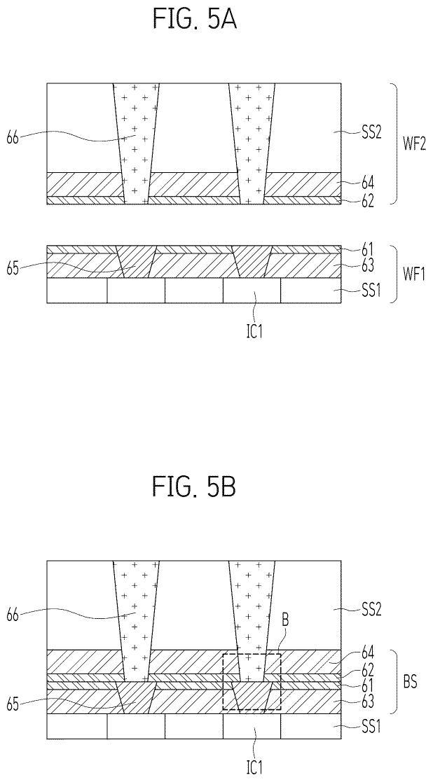

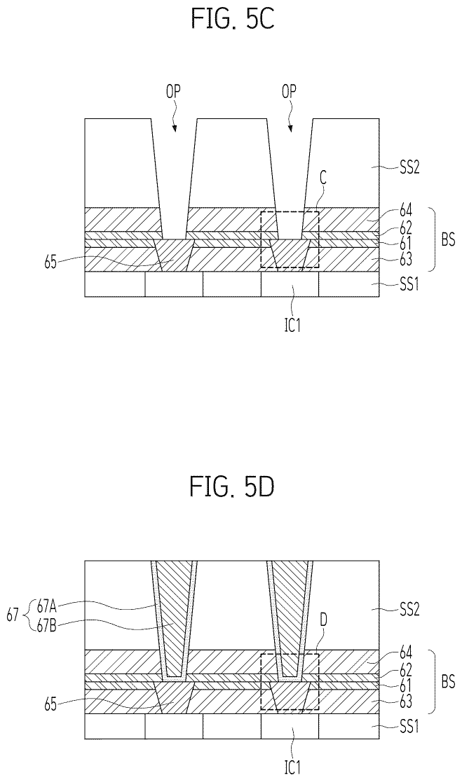

FIGS. 5A to 5D are diagrams illustrating a method of manufacturing a semiconductor device according to an embodiment of the present disclosure. Hereinafter, a description that overlaps the content described above may be omitted.

Referring to FIG. 5A, a first wafer WF1 including a first bonding layer 61 and a bonding pad 65 may be formed. The first wafer WF1 may further include a first semiconductor structure SS1 such as a peripheral circuit and a memory cell array. The first semiconductor structure SS1 may include a first interconnection structure IC1, and the bonding pad 65 may be connected to the first interconnection structure IC1. The first wafer WF1 may further include a first bonding insulating layer 63 disposed between the first bonding layer 61 and the first semiconductor structure SS1. The bonding pad 65 may pass through the first bonding layer 61 and the first bonding insulating layer 63. The first bonding layer 61 may include SiCN, and the first bonding insulating layer 63 may include an insulating material such as oxide or nitride.

A second wafer WF2 including a second bonding layer 62 and a sacrificial plug 66 may be formed. The second wafer WF2 may further include a second semiconductor structure SS2 such as a peripheral circuit and a memory cell array. The second wafer WF2 may further include a second bonding insulating layer 64, and the sacrificial plug 66 may pass through the second semiconductor structure SS2, the second bonding layer 62, and the second bonding insulating layer 64. The second bonding layer 62 may include SiCN, and the second bonding insulating layer 64 may include an insulating material such as oxide or nitride. The sacrificial plug 66 may include a material with a high etch selectivity with respect to the second bonding layer 62 and the second bonding insulating layer 64. The sacrificial plug 66 may include a conductive material such as tungsten, polysilicon, titanium nitride, or an insulating material such as nitride.

Referring to FIG. 5B, the first bonding layer 61 and the second bonding layer 62 may be bonded so that the bonding pad 65 and the sacrificial plug 66 are connected. Through this, a bonding structure BS may be formed. Through bonding, a surface of the first bonding layer 61 and a surface of the second bonding layer 62 may be chemically bonded. In an embodiment, carbon (C) and nitrogen (N) of the SiCN layer may be removed, and Si—O—Si bonding may be generated. The bonding pad 65 and the sacrificial plug 66 may be connected to each other by directly contacting each other without chemical bonding.

Referring to FIG. 5C, the sacrificial plug 66 may be removed to form an opening OP. The opening OP may pass through the second semiconductor structure SS2, the second bonding insulating layer 64 and the second bonding layer 62 to expose at least partially the top surface of the bonding pad 65. The opening OP may have a high aspect ratio. Also, the second bonding layer 62 and the second bonding insulating layer 64 may be exposed through the opening OP.

Referring to FIG. 5D, a contact plug 67 electrically connected to the bonding pad 65 may be formed in the opening OP. The contact plug 67 may be formed by depositing a conductive material along a surface of the bonding pad 65 and an inner surface of the opening OP. A barrier layer 67A may be formed in the opening OP, and a metal layer 67B may be formed in the barrier layer 67A.

According to the manufacturing method described above, after bonding the first wafer WF1 and the second wafer WF2, the sacrificial plug 66 may be replaced with the contact plug 67. The bonding pad 65 and the sacrificial plug 66 may not be chemically bonded, and the contact plug 67 may be formed by depositing a conductive material on the bonding pad 65. Therefore, the bonding pad 65 and the contact plug 67 may be electrically connected even though the bonding pad 65 and the contact plug 67 are not directly bonded.

In order to directly bond bonding pads, both of the bonding pad 65 and the contact plug 67 are required to be formed of copper, but according to an embodiment of the present disclosure, a material of the bonding pad 65 and the contact plug 67 may not be limited to copper. In an embodiment, the bonding pad 65 and the contact plug 67 may be formed of a material such as tungsten-tungsten of which a use is difficult due to a restriction due to a thermal process, or the bonding pad 65 and the contact plug 67 may be formed of different types of materials such as copper-tungsten.

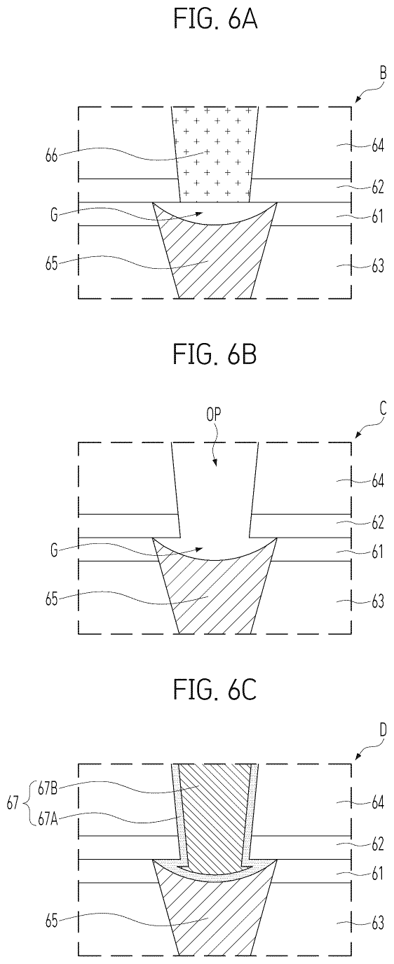

FIGS. 6A to 6C are diagrams illustrating a method of manufacturing a semiconductor device according to an embodiment of the present disclosure. FIG. 6A is an enlarged view of a region B of FIG. 5B, FIG. 6B is an enlarged view of a region C of FIG. 5C, and FIG. 6C is an enlarged view of a region D of FIG. 5D. Hereinafter, a description that overlaps the content described above may be omitted.

Referring to FIG. 6A, the bonding pad 65 and the sacrificial plug 66 may be connected by bonding the first bonding layer 61 and the second bonding layer 62. At this time, a gap G may exist between the bonding pad 65 and the sacrificial plug 66. The gap G may be caused by dishing induced in a planarization process for forming the bonding pad 65. Due to the dishing, an upper surface of the bonding pad 65 may be positioned lower than an upper surface of the first bonding layer 61. In this case, the first bonding layer 61 and the second bonding layer 62 may be in contact with each other to be bonded to each other, but the gap G may exist between the bonding pad 65 and the sacrificial plug 66, and the first bonding layer 61 and the second bonding layer 62 may not be in contact with each other.

Referring to FIG. 6B, the sacrificial plug 66 may be removed to form an opening OP. The opening OP may be connected to the gap G and extend into the first bonding layer 61.

Referring to FIG. 6C, the contact plug 67 may be formed in the opening OP. In an embodiment, after forming the barrier layer 67A in the opening OP, the metal layer 67B may be formed. In an embodiment, the opening OP may be filled with the metal layer 67B without forming the barrier layer 67A.

According to the manufacturing method described above, the contact plug 67 may be formed after wafer bonding. Therefore, even though the gap G is formed between the bonding pad 65 and the sacrificial plug 66, the gap G may be filled with the contact plug 67. Therefore, the bonding pad 65 and the contact plug 67 may be connected without the gap G, and an ohmic contact may be formed.

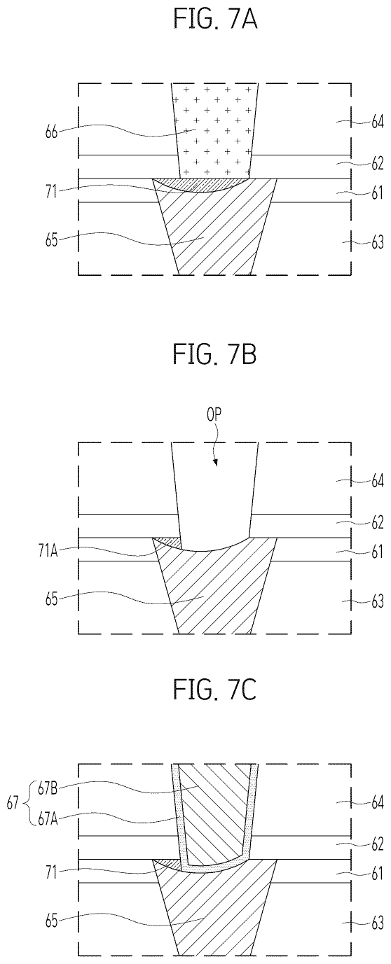

FIGS. 7A to 7C are diagrams illustrating a method of manufacturing a semiconductor device according to an embodiment of the present disclosure. FIG. 7A is an enlarged view of a region B of FIG. 5B, FIG. 7B is an enlarged view of a region C of FIG. 5C, and FIG. 7C is an enlarged view of a region D of FIG. 5D. Hereinafter, a description that overlaps the content described above may be omitted.

Referring to FIG. 7A, the bonding pad 65 and the sacrificial plug 66 may be connected by bonding the first bonding layer 61 and the second bonding layer 62. At this time, a foreign substance 71 may exist between the bonding pad 65 and the sacrificial plug 66. The foreign substance 71 may be a by-product in a manufacturing process, and may be an etching residue, a bonding residue, or the like. The foreign substance 71 may be a polymer-based material, and due to the foreign substance 71, the bonding pad 65 and the sacrificial plug 66 may not be directly connected or a contact area between them may be reduced.

Referring to FIG. 7B, the sacrificial plug 66 may be removed to form an opening OP. The foreign substance 71 may be exposed through the opening OP, and at least a portion of the exposed foreign substance 71 may be removed. In an embodiment, the sacrificial plug 66 may be removed through a deep-out process and then the foreign substance 71 may be removed through an etching process. A portion of the foreign substance 71 exposed by the opening OP may be removed, and a portion interposed between the bonding pad 65 and the second bonding layer 62 may remain without being removed.

Referring to FIG. 7C, the contact plug 67 may be formed in the opening OP. In an embodiment, after forming the barrier layer 67A in the opening OP, the metal layer 67B may be formed. In an embodiment, the opening OP may be filled with the metal layer 67B without forming the barrier layer 67A.

According to the manufacturing method described above, the contact plug 67 may be formed after wafer bonding. Therefore, even when the foreign substance 71 exists between the bonding pad 65 and the sacrificial plug 66, the foreign substance 71 may be removed by the process of replacing the sacrificial plug 66 with the contact plug 67. Therefore, the bonding pad 65 and the contact plug 67 may be connected without the foreign substance 71, and an ohmic contact may be formed.

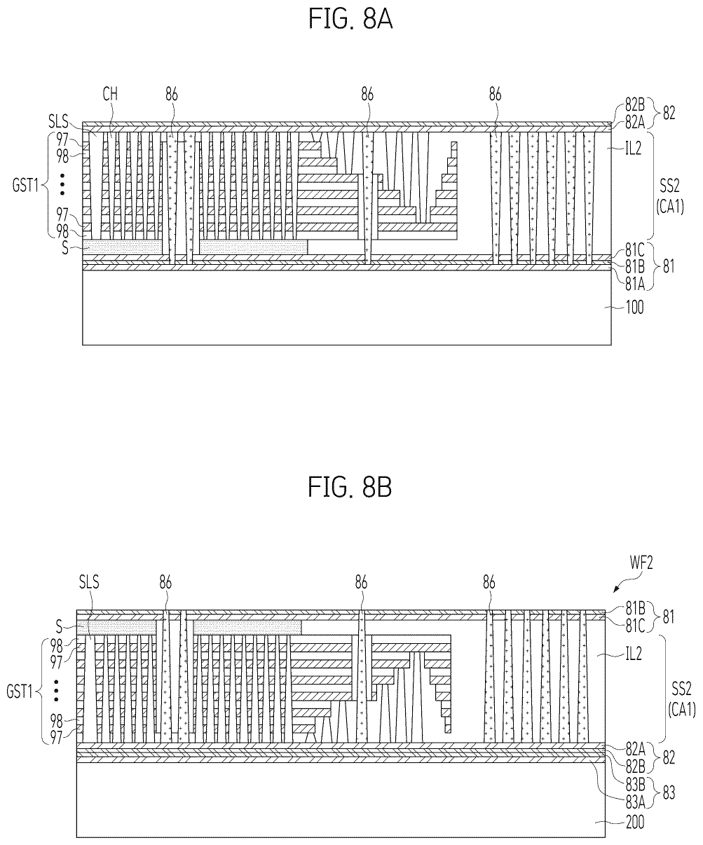

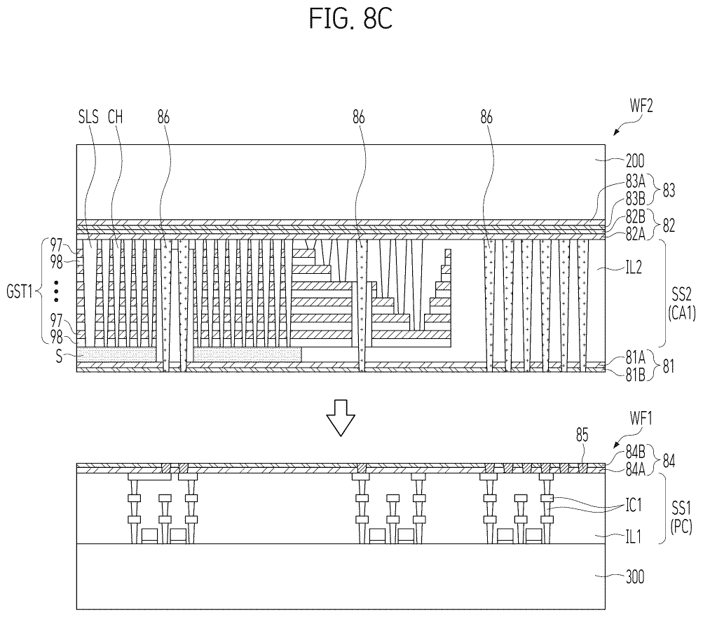

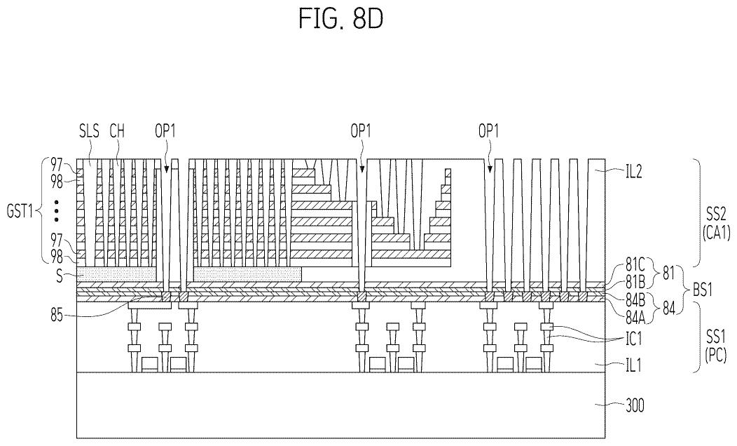

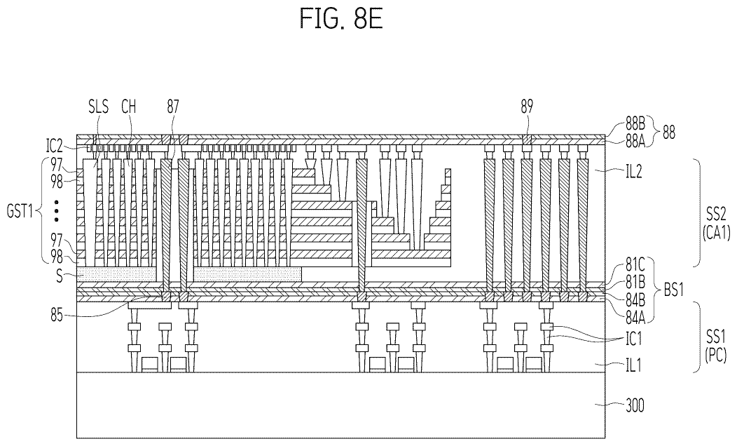

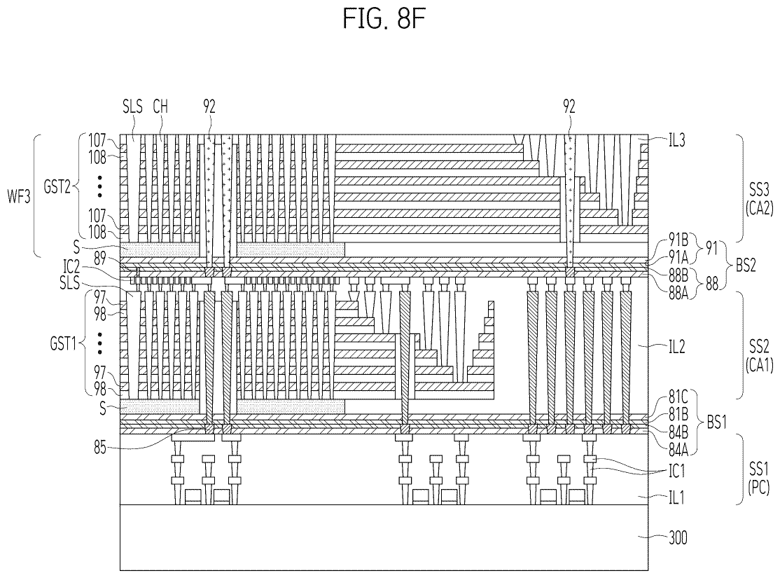

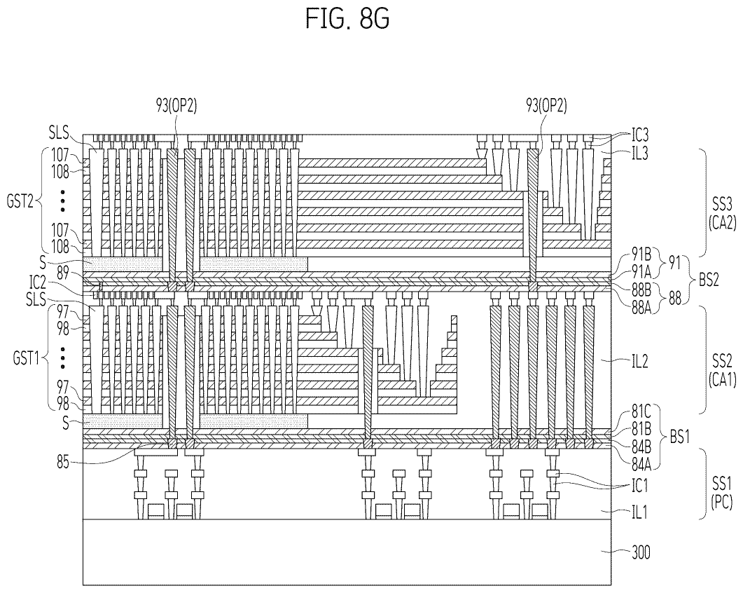

FIGS. 8A to 8G are diagrams illustrating a method of manufacturing a semiconductor device according to an embodiment of the present disclosure. Hereinafter, a description that overlaps the content described above may be omitted.

Referring to FIGS. 8A and 8B, a second wafer WF2 including a first sacrificial plug 86 and a second bonding layer 81B may be formed.

First, referring to FIG. 8A, a first preliminary bonding structure 81 may be formed on a second substrate 100. The first preliminary bonding structure 81 may include a second bonding layer 81B. The first preliminary bonding structure 81 may further include bonding insulating layers 81A and 81C. The second bonding layer 81B may be interposed between the bonding insulating layers 81A and 81C. The bonding insulating layers 81A and 81C may be made of an insulating material such as an oxide or nitride suitable for protecting the second bonding layer 81B in a manufacturing process. The second bonding layer 81B may form a bonding interface through chemical bonding, and may include SiCN.

Subsequently, a second semiconductor structure SS2 may be formed on the first preliminary bonding structure 81. The second semiconductor structure SS2 may include a first memory cell array CA1. The second semiconductor structure SS2 may include a first sacrificial plug 86, a source structure S, a first gate structure GST1, a channel structure CH, a slit structure SLS, and a second interlayer insulating layer IL2. The gate structure GST may include gate lines 97 and insulating layers 98 that are alternately stacked. The first sacrificial plug 86 may extend through the first gate structure GST1 and the source structure S, or may extend through the second interlayer insulating layer IL2. The first sacrificial plug 86 may extend into the first preliminary bonding structure 81. In an embodiment, the first sacrificial plug 86 may pass through the second bonding insulating layer 81C and the first bonding layer 81B and contact the top surface of the first bonding insulating layer 81A.

In an embodiment, the second semiconductor structure SS2 may include a stack instead of the gate structure GST. The stack may include sacrificial layers instead of the gate lines 97. The stack may include the sacrificial layers and insulating layers 98 that are alternately stacked. In this case, a sacrificial slit structure may be formed instead of the slit structure SLS.

Subsequently, a first sacrificial bonding structure 82 may be formed on the second semiconductor structure SS2. The first sacrificial bonding structure 82 may include a first sacrificial bonding layer 82B and may further include a first sacrificial bonding insulating layer 82A, with the first sacrificial bonding insulating layer 82A being disposed between the first sacrificial bonding layer 82B and the second interlayer insulating layer IL2. The first sacrificial bonding insulating layer 82A may be formed on the second semiconductor structure SS2.

Subsequently, referring to FIG. 8B, a second sacrificial bonding structure 83 may be formed on a carrier wafer 200. The second sacrificial bonding structure 83 may include a second sacrificial bonding layer 83B, and may further include a second sacrificial bonding insulating layer 83A.

Subsequently, the first sacrificial bonding layer 82B and the second sacrificial bonding layer 83B may be bonded and the second substrate 100 and the bonding insulating layer 81A may be removed. Through this, a second wafer W2 in which the second semiconductor structure SS2 is bonded to the carrier wafer 200 may be formed.

Referring to FIG. 8C, a first wafer WF1 including a first bonding pad 85 and a first bonding layer 84B may be formed. First, the first semiconductor structure SS1 may be formed on a first substrate 300. The first semiconductor structure SS1 may include a peripheral circuit PC, and the peripheral circuit PC may include a page buffer, a row decoder, a logic circuit, an analog circuit, an input/output circuit, or the like. The first semiconductor structure SS1 may further include a first interlayer insulating layer IL1 and a first interconnection structure IC1.

Subsequently, a second preliminary bonding structure 84 may be formed on the peripheral circuit PC. The second preliminary bonding structure 84 may include a first bonding layer 84B and a first bonding pad 85, and may further include a bonding insulating layer 84a. The first bonding pad 85 may pass through the first bonding layer 84B and the bonding insulating layer 84a to electrically connect to the peripheral circuit PC through the first interconnection structure IC1.

Subsequently, the first wafer WF1 and the second wafer WF2 may be bonded. The first bonding layer 84B and the second bonding layer 81B may be bonded so that the first sacrificial plug 86 and the first bonding pad 85 are connected. Through this, surfaces of the first bonding layer 84B and the second bonding layer 81B may be chemically bonded. The first sacrificial plug 86 and the first bonding pad 85 may be in physical contact without chemical bonding. A gap may exist between the first sacrificial plug 86 and the first bonding pad 85, or a foreign substance may be interposed.

Referring to FIG. 8D, the first preliminary bonding structure 81 and the second preliminary bonding structure 84 may be bonded to thus form a first bonding structure BS1. Subsequently, the carrier wafer 200, the second sacrificial bonding structure 83, and the first sacrificial bonding structure 82 may be removed to expose the second semiconductor structure SS2 and the first sacrificial plug 86.

Subsequently, the first sacrificial plug 86 may be removed to form a first opening OP1 by selective etching. The first opening OP1 is formed to expose the first bonding pad 85.

If a gap exists between the first sacrificial plug 86 and the first bonding pad 85, then the gap is exposed through the first opening OP1. Likewise, if a foreign substance exists between the first sacrificial plug 86 and the first bonding pad 85, the foreign substance is also exposed through the first opening OP1.

Referring to FIG. 8E, a first contact plug 87 may be formed in the first opening OP1. The first contact plug 87 may be electrically connected to the first bonding pad 85. When a gap exists between the first sacrificial plug 86 and the first bonding pad 85, the first contact plug 87 may be formed in the first opening OP1 and the gap. When a foreign substance exists between the first sacrificial plug 86 and the first bonding pad 85, the first contact plug 87 may be formed after removing the foreign substance. Through this, a bonding defect may be reduced.

In an embodiment, when the second semiconductor structure SS2 includes a stack and a sacrificial slit structure, the sacrificial slit structure may be removed to form a slit, and sacrificial layers may be replaced with gate lines 97 through the slit. Subsequently, the slit structure SLS may be formed in the slit. Through this, the gate structure GST may be formed.

Subsequently, a second interconnection structure IC2 connected to the first contact plug 87, the channel structure CH, the slit structure SLS, and the like may be formed. Subsequently, a third preliminary bonding structure 88 may be formed. The third preliminary bonding structure 88 may include a third bonding layer 88B and a second bonding pad 89, and may further include a bonding insulating layer 88A. The second bonding pad 89 may extend through the third bonding layer 88B and the bonding insulating layer 88A to electrically connect to the second interconnection structure IC2. The second bonding pad 89 may be electrically connected to the first contact plug 87.

Referring to FIG. 8F, a third wafer WF3 including a fourth bonding layer 91A and a second sacrificial plug 92 may be formed. The third wafer W3 may include a fourth preliminary bonding structure 91. The fourth preliminary bonding structure 91 may include the fourth bonding layer 91A and may further include a bonding insulating layer 91B.

The third wafer WF3 may include a third semiconductor structure SS3. The third semiconductor structure SS3 may include a second memory cell array CA2. The third semiconductor structure SS3 may include the second sacrificial plug 92, the source structure S, the second gate structure GST2, the channel structure CH, the slit structure SLS, and the third interlayer insulating layer IL3. The second gate structure GST2 may include gate lines 107 and insulating layers 108 that are alternately stacked. The second sacrificial plug 92 may extend through the second gate structure GST2 and the source structure S, or may extend through the third interlayer insulating layer IL3. The second sacrificial plug 92 may extend into the fourth preliminary bonding structure 91. In an embodiment, the second sacrificial plug 92 may pass through the bonding insulating layer 91B and the fourth bonding layer 91A.

Subsequently, the third bonding layer 88B and the fourth bonding layer 91A may be bonded so that the second sacrificial plug 92 and the second bonding pad 89 are connected. The third bonding layer 88B and the fourth bonding layer 91A may be bonded, and thus a second bonding structure BS2 may be formed. When bonding the third wafer WF3, as previously described with reference to FIGS. 8A to 8C, a carrier wafer may be used, and the carrier wafer may be removed to expose the second sacrificial plug 92.

Referring to FIG. 8G, the second sacrificial plug 92 may be removed to form a second opening OP2 exposing the second bonding pad 89. Subsequently, a second contact plug 93 may be formed in the second opening OP2. The second contact plug 93 may be directly connected to the second bonding pad 89.

Subsequently, a third interconnection structure IC3 connected to the second contact plug 93, the channel structure CH, the slit structure SLS, and the like may be formed.

According to the manufacturing method described above, a sacrificial plug may be formed when forming a wafer, and the sacrificial plug may be replaced with a contact plug after wafer bonding. Therefore, instead of making a bond between bonding pads, the bonding pad and the contact plug may be directly connected. In a conventional method of making a bond between two bonding pads, the material of the bonding pads is typically limited to copper. However, according to embodiments of the present disclosure, an expanded range of materials may be used for the bonding pad and the contact plug.

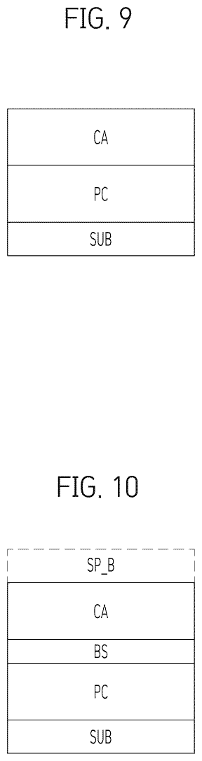

The structure and the manufacturing method according to the above-described embodiments may be applied to semiconductor devices of various structures. FIGS. 9 and 10 illustrate a schematic configuration of a semiconductor device to which the above-described embodiments are applicable.

FIG. 9 is a configuration diagram of a semiconductor device according to an embodiment of the present invention disclosure.

Referring to FIG. 9, the semiconductor device may include a substrate SUB, a peripheral circuit PC formed over the substrate SUB, and a memory cell array CA formed over the peripheral circuit PC. In the illustrated embodiment, the peripheral circuit PC and the memory cell array CA may be formed over or on the same substrate SUB.

The substrate SUB may be made of or include a semiconductor material. In an embodiment, the semiconductor material may include at least one of a group IV semiconductor, a group III-V compound semiconductor, and a group II-VI compound semiconductor. For example, the group IV semiconductor may include single crystal silicon Si, polycrystalline silicon, germanium Ge, or silicon germanium SiGe. The group III-V compound semiconductor may include GaAs, GaN, GaP, GaAsP, GaInAsP, AlAs, AlGa, InP, InSb, or InGaAs. The group II-VI compound semiconductor may include ZnS, ZnO, or CdS.

The substrate SUB may include a dielectric layer. The substrate SUB may be a silicon-on-insulator (SOI) substrate, a germanium-on-insulator (GeOI) substrate, or a glass substrate. The substrate SUB may include an organic material. In an embodiment, the substrate SUB may include graphene.

The substrate SUB may be a bulk wafer or an epitaxial layer grown in a selective epitaxial growth (SEG) method. The substrate SUB may be a layer formed in a metal induced lateral crystallization (MILC) method and may partially include metal. The substrate SUB may have a single crystalline, polycrystalline, or amorphous state. The substrate SUB may include an impurity of group II, group III, group IV, group V, or group VI. In an embodiment, the substrate SUB may include an n-well region doped with an n-type impurity and/or a p-well region doped with a p-type impurity.

The peripheral circuit PC may be disposed between the substrate SUB and the memory cell array CA. The peripheral circuit PC may include a row decoder, a column decoder, a page buffer, a logic circuit, a control circuit, a sense amplifier, an input/output circuit, and the like. In an embodiment, the peripheral circuit PC may include an NMOS transistor, a PMOS transistor, a resistor, a capacitor, and the like. The peripheral circuit PC may further include an interconnection structure. The interconnection structure may be used as a path for transferring an operation voltage, and may include a contact plug, a line, and the like.

The memory cell array CA may include memory cells. In an embodiment, the memory cell array CA may include memory strings connected between a source line and a bit line, and each memory string may include stacked memory cells. In an embodiment, the memory cell array CA may include memory cells connected between a word line and a bit line. The memory cell array CA may further include an interconnection structure.

FIG. 10 is a configuration diagram of a semiconductor device according to an embodiment of the present disclosure.

Referring to FIG. 10, the semiconductor device may include a substrate SUB, a peripheral circuit PC, a bonding structure BS, and a memory cell array CA. For example, the peripheral circuit PC and the memory cell array CA may be respectively formed on separate substrates and then bonded. The semiconductor device may further include a support base SP_B.

The substrate SUB may be used as a support by the process of forming the peripheral circuit PC. The support base SP_B may be used as a support by the process of forming the memory cell array CA. In an embodiment, after respectively manufacturing a first wafer including the memory cell array CA and a second wafer including the peripheral circuit PC, the first wafer and the second wafer may be electrically connected by the bonding structure BS. After bonding, at least a portion of the support base SP_B of the first wafer may be removed. The support base SP_B may be completely removed or may partially remain on the memory cell CA array.

The support base SP_B may be a semiconductor substrate, an insulating substrate, a silicon-on-insulator (SOI) substrate, a germanium-on-insulator (GeOI) substrate, or the like. The support base SP_B may be a bulk wafer, an epitaxial layer grown in a selective epitaxial growth (SEG) method, or a layer formed in a metal induced lateral crystallization (MILC) method. The support base SP_B may have a single crystalline, polycrystalline, or amorphous state. The support base SP_B may include an impurity of group II, group III, group IV, group V, or group VI.

The bonding structure BS may connect the memory cell array CA and the peripheral circuit PC. In an embodiment, the memory cell array CA and the peripheral circuit PC may be bonded in a wafer-on-wafer bonding method, a chip-on-wafer bonding method, a chip-on-chip bonding method, or the like. The bonding structure BS may include a bonding pad, a bonding layer, a bonding interface, and the like. The bonding pad may include a metal such as copper and aluminum, and/or an alloy. The bonding interface may include a non-metal-non-metal interface, a metal-metal interface, or the like. The memory cell array CA and the peripheral circuit PC may be electrically connected by the bonding structure BS.

In an embodiment, an interconnection structure included in the memory cell array CA and/or the peripheral circuit PC may be directly connected without a bonding pad. In an embodiment, a bonding layer included in the memory cell array CA and a bonding layer included in the peripheral circuit PC may be bonded to form a bonding interface, and the interconnection structure included in the memory cell array CA and the interconnection structure included in the peripheral circuit PC may be directly connected. Through this, contact plugs, lines, and the like formed on different wafers may be electrically connected without a separate bonding pad.

Other configurations may be equal or similar to those described above with reference to FIG. 9.

The semiconductor device may have a structure in which the embodiments described above with reference to FIGS. 9 and 10 are combined or may have a partially modified structure. In the embodiment described with reference to FIGS. 9 and 10, positions of the memory cell array CA and the peripheral circuit PC may be changed. At least one memory cell array CA and/or at least one peripheral circuit PC may be additionally bonded to the embodiment described with reference to FIG. 9. In an embodiment, a portion of the peripheral circuitry PC may be disposed in the memory cell array CA.

Although embodiments according to the technical concepts of the present disclosure have been described with reference to the accompanying drawings, this is only for describing an embodiment according to the concept of the present disclosure, and the present disclosure is not limited to the above-described embodiments. Within the scope of the technical concepts of the present disclosure, various forms of substitution, modification, change, and combination of the embodiments will be possible by those skilled in the art to which the present disclosure belongs, and these also belong to the scope of the present disclosure. Furthermore, the embodiments may be combined to form additional embodiments.

What is claimed is:

1. A semiconductor device comprising:
a first semiconductor structure including a peripheral circuit and an interconnection structure electrically connected to the peripheral circuit;
a second semiconductor structure;
a bonding layer positioned between the first and second semiconductor structures;
a bonding pad electrically connected to the interconnection structure, the bonding pad extending into the bonding layer; and
a contact plug extending into the bonding layer through the second semiconductor structure,
wherein the contact plug is electrically connected to the bonding pad.

2. The semiconductor device of claim 1, wherein the bonding layer comprises first and second bonding layers, the second bonding layer being positioned between the first bonding layer and the second semiconductor structure,
wherein the second bonding layer forms a bonding interface with the first bonding layer,
wherein the bonding pad passes through the first bonding layer, and
wherein the contact plug passes through the second bonding layer to connect with the bonding pad at the bonding interface.

3. The semiconductor device of claim 1, wherein the second semiconductor structure includes a gate structure, a channel structure extending through the gate structure, and memory cells stacked along the channel structure, and wherein the contact plug extends through the gate structure.

4. The semiconductor device of claim 3, wherein the second semiconductor structure further includes a source structure positioned under the gate structure, and wherein the contact plug passes through the source structure.

5. The semiconductor device of claim 3, wherein the contact plug electrically connects a page buffer of the first semiconductor structure and a bit line of the second semiconductor structure.

6. The semiconductor device of claim 3, wherein the contact plug electrically connects a row decoder of the first semiconductor structure and a gate line of the second semiconductor structure.

7. The semiconductor device of claim 1, wherein the contact plug includes a barrier layer and a metal layer in the barrier layer.

8. The semiconductor device of claim 7, wherein the barrier layer extends between the metal layer and the bonding pad.

9. The semiconductor device of claim 1, wherein the second semiconductor structure includes an interlayer insulating layer and an uppermost metal line, and
wherein the contact plug extends through the interlayer insulating layer to electrically connect to the uppermost metal line.

10. The semiconductor device of claim 9, wherein the contact plug electrically connects the peripheral circuit of the first semiconductor structure and the uppermost metal line of the second semiconductor structure.

11. The semiconductor device of claim 1, wherein the contact plug comprises:
a through portion passing through the second bonding layer and extending into the second semiconductor structure; and
an extension portion expanding into the first bonding layer and having a width greater than that of the through portion.

12. The semiconductor device of claim 1, wherein a lower surface of the contact plug includes a curved surface.

13. The semiconductor device of claim 1, further comprising:
a first bonding insulating layer positioned between the first bonding layer and the first semiconductor structure,
wherein the bonding pad passes through the first bonding insulating layer.

14. The semiconductor device of claim 1, further comprising:
a second bonding insulating layer positioned between the second bonding layer and the second semiconductor structure,
wherein the contact plug passes through the second bonding insulating layer.

15. A semiconductor device comprising:
a first bonding layer;
a first bonding pad passing through the first bonding layer;
a second bonding layer forming a bonding interface with the first bonding layer;
a first gate structure on the second bonding layer; and
a first contact plug extending through the first gate structure and the second bonding layer and electrically connected to the first bonding pad,
wherein the first contact plug comprises:
a metal layer; and
a barrier layer surrounding a sidewall of the metal layer and extending between the metal layer and the first bonding pad.

16. The semiconductor device of claim 15, wherein the barrier layer and the first bonding pad contact.

17. The semiconductor device of claim 15, further comprising:
a third bonding layer positioned on the first gate structure;
a second bonding pad passing through the third bonding layer and electrically connected to the first contact plug;
a fourth bonding layer forming a bonding interface with the third bonding layer;
a second gate structure on the fourth bonding layer; and
a second contact plug extending through the second gate structure and the fourth bonding layer and electrically connected to the second bonding pad.

18. The semiconductor device of claim 15, further comprising:
a page buffer positioned under the first bonding layer and electrically connected to the first contact plug through the first bonding pad.

19. The semiconductor device of claim 15, further comprising:
a row decoder positioned under the first bonding layer and electrically connected to the first contact plug through the first bonding pad.

20. A method of manufacturing a semiconductor device, the method comprising:
forming a first wafer including a first bonding layer and a first bonding pad;
forming a second wafer including a second bonding layer and a first sacrificial plug;
bonding the first bonding layer and the second bonding layer so that the first bonding pad and the first sacrificial plug are connected;
forming a first opening exposing the first bonding pad by removing the first sacrificial plug; and
forming a first contact plug electrically connected to the first bonding pad, in the first opening.

21. The method of claim 20, wherein forming the first wafer comprises:
forming a peripheral circuit on the first substrate;
forming the first bonding layer on the peripheral circuit; and
forming the first bonding pad passing through the first bonding layer and electrically connected to the peripheral circuit.

22. The method of claim 20, wherein forming the second wafer comprises:
forming the second bonding layer on a second substrate;
forming a gate structure on the second bonding layer; and
forming the first sacrificial plug extending through the gate structure and the second bonding layer.

23. The method of claim 22, wherein forming the second wafer comprises:
forming a sacrificial bonding layer on the gate structure;
bonding a carrier wafer to the sacrificial bonding layer; and
removing the second substrate.

24. The method of claim 23, further comprising:
after bonding the first bonding layer and the second bonding layer, removing the carrier wafer; and
removing the sacrificial bonding layer.

25. The method of claim 20, wherein forming the first contact plug comprises:
forming a barrier layer in the first opening; and
forming a metal layer in the barrier layer.

26. The method of claim 20, wherein in bonding the first bonding layer and the second bonding layer, the first bonding layer and the second bonding layer contact, and a gap exists between the first bonding pad and the first sacrificial plug.

27. The method of claim 26, wherein forming the first contact plug comprises forming the first contact plug in the first opening and the gap.

28. The method of claim 20, further comprising:
forming a third bonding layer on the first contact plug;
forming a second bonding pad passing through the third bonding layer and electrically connected to the first contact plug;
forming a third wafer including a second sacrificial plug and a fourth bonding layer;
bonding the third bonding layer and the fourth bonding layer so that the second sacrificial plug and the second bonding pad are connected;
forming a second opening exposing the second bonding pad by removing the second sacrificial plug; and
forming a second contact plug in the second opening.

29. The method of claim 20, further comprising:
before forming the first contact plug, removing a foreign substance exposed through the first opening.
